(19) United States
(12) Patent Application Publication
(10) Pub. No.: US 2018/0190556 A1
(43) Pub. Date: Jul. 5, 2018

(54) METHODS AND APPARATUS FOR SPARK GAP DEVICES WITHIN INTEGRATED CIRCUITS

(71) Applicant: Texas Instruments Incorporated, Dallas, TX (US)

(72) Inventors: Barry Jon Male, West Granby, CT (US); Steve Kummerl, Carrollton, TX (US); Robert Alan Neidorff, Bedford, NH (US); Benjamin Stassen Cook, Addison, TX (US)

(21) Appl. No.: 15/396,121

(22) Filed: Dec. 30, 2016

(51) Int. Cl. H01L 23/31; H02H 9/04; H01L 23/495; H01L 27/02; H01L 21/48; H01L 21/56

(52) U.S. Cl. CPC H01L 23/315; H02H 9/046; H01L 23/49503; H01L 23/4952; H01L 23/49575; H01L 27/0248; H01L 21/4825; H01L 21/565; H01L 23/49541

(57) ABSTRACT

In a described example, an apparatus includes: an integrated circuit die having multiple terminals; a leadframe having leads for external connections, at least some of the leads electrically coupled to at least one of the multiple terminals of the integrated circuit die; a first electrode having a first end portion; a second electrode having a second end portion positioned proximal to and spaced apart from the first end portion of the first electrode, the first end portion and the second end portion spaced by a spark gap; encapsulation material surrounding the integrated circuit die to form a packaged integrated circuit having a cavity surrounding the first end portion, the second end portion, and the spark gap so that the first end portion of the first electrode, the second end portion of the second electrode and the spark gap are spaced from the encapsulation material.

### CROSS-REFERENCE TO RELATED APPLICATIONS

This application relates to co-owned and co-assigned U.S. patent application Ser. No. 15/395,817, Attorney Docket No. TI-77357, entitled “METHODS AND APPARATUS FOR INTEGRATED CIRCUIT FAILSAFE FUSE PACKAGE WITH ARC ARREST,” filed Dec. 30, 2016, naming Barry Jon Male et. al. as inventors, and to co-owned and co-assigned U.S. patent application Ser. No. 15/248,151 (the '151 Application), Attorney Docket No. TI-76980, filed Aug. 26, 2016, entitled “FLOATING DIE PACKAGE,” naming Benjamin Stassen Cook as inventor, which applications are each hereby incorporated by reference in their entirety herein.

### TECHNICAL FIELD

This relates generally to spark gap devices for ESD protection, and more particularly to spark gap devices with an air dielectric formed within integrated circuits for ESD protection.

### BACKGROUND

Spark gap devices are known and are used to protect circuitry from transient overvoltage such as lighting strikes or ESD protection. Electrode shapes and materials are known and are selected to meet the needs of the application. Physicist Friedrich Paschen published data showing the voltages required to start an electric arc with respect to the electrode spacing in various gases. These are known as “Paschen Curves” and from those curves, electrode spacing for a spark gap device is known. In a basic conventional spark gap device, two electrodes are arranged so that when the potential between the electrodes exceeds a threshold voltage, the gas between them will break down forming a spark or an arc. Electrical arcs, sometimes referred to as plasma arcs, are very high temperature events, with temperatures in the plasma being several thousand degrees centigrade. The high temperature from the plasma arc heats the surrounding air, creates localized high pressure and can vaporize a portion of the electrode material. In this application, the high temperature plasma arc will be referred to by the shortened term “arc”. After the plasma arc is initiated, the arc creates a “short” or a very low resistance path that conducts the high voltage energy until the conditions required to sustain the arc no longer exist Sparks due to static electricity are simply quickly extinguishing arcs. To protect a circuit with a spark gap device, the first electrode is connected to the circuit to be protected and the second electrode is connected to earth ground. When a transient voltage exceeds the voltage threshold of the spark gap device, an arc is initiated between the electrodes and the transient energy is diverted to ground, thus protecting the circuitry from current due to an over voltage.

One of the drawbacks of using a single electrode is that an arc can heat the electrode and consume part of the electrode each time the arc conducts energy. The erosion of the electrodes changes the spacing and therefore the threshold voltage. To help alleviate this issue, multiple electrodes are sometimes used.

In another approach, a spark gap device is created on an integrated circuit using a top level metal for the electrodes. However, the relatively thin metal used to form conductors in semiconductor processes is not well suited for the repeated arcs that an ESD protection device can encounter.

In another approach, electrodes are formed by micromachining columns within a semiconductor process to form conductive columns or pillars surrounded by a dielectric material to create the electrodes of the spark gap device. Further innovation on integrated spark gap ESD protection devices is therefore needed.

### SUMMARY

In a described example, an apparatus includes: an integrated circuit die having multiple terminals; a leadframe having a die pad portion, the integrated circuit die positioned on and attached to the die pad portion; the leadframe having leads for external connections, at least some of the leads having an inner portion electrically coupled to at least one terminal selected from the multiple terminals of the integrated circuit die; a first electrode having a first end portion; a second electrode having a second end portion positioned proximal to and spaced from the first end portion of the first electrode, the first end portion and the second end portion spaced by a spark gap; and encapsulation material surrounding the integrated circuit die and the first and second electrodes and the spark gap to form a packaged integrated circuit having a cavity in the encapsulation material surrounding the first end portion of the first electrode, the second end portion of the second electrode, and the spark gap, the first end portion of the first electrode, the second end portion of the second electrode and the spark gap spaced from the encapsulation material.

### BRIEF DESCRIPTION OF THE DRAWINGS

FIG. 1 is a top view of a pillar style spark gap ESD device.

FIG. 2 is a cross sectional view of a conventional spark gap ESD device.

FIG. 3 is a top view of an example embodiment providing a spark gap ESD protection device.

FIG. 4 is a cross sectional view of another example embodiment for a spark gap ESD protection device within an integrated circuit package.

FIGS. 5A and 5B are a top view and a cross section, respectively, of another example embodiment for a spark gap ESD protection device for isolated sub-die in a package.

FIGS. 6A and 6B are a top view and a cross section, respectively, of another example embodiment 600 for a spark gap ESD protection device for a stacked die package.

FIG. 7 is a cross sectional view of an additional example embodiment for a spark gap ESD protection device formed within an integrated circuit package.

FIG. 8 shows in a flow diagram a method embodiment.

### DETAILED DESCRIPTION OF EXAMPLE EMBODIMENTS

Corresponding numerals and symbols in the different figures generally refer to corresponding parts unless otherwise indicated. The figures are not necessarily drawn to scale. The term “coupled” can include connections made with intervening elements, and additional elements and various connections can exist between any elements that are “coupled.”

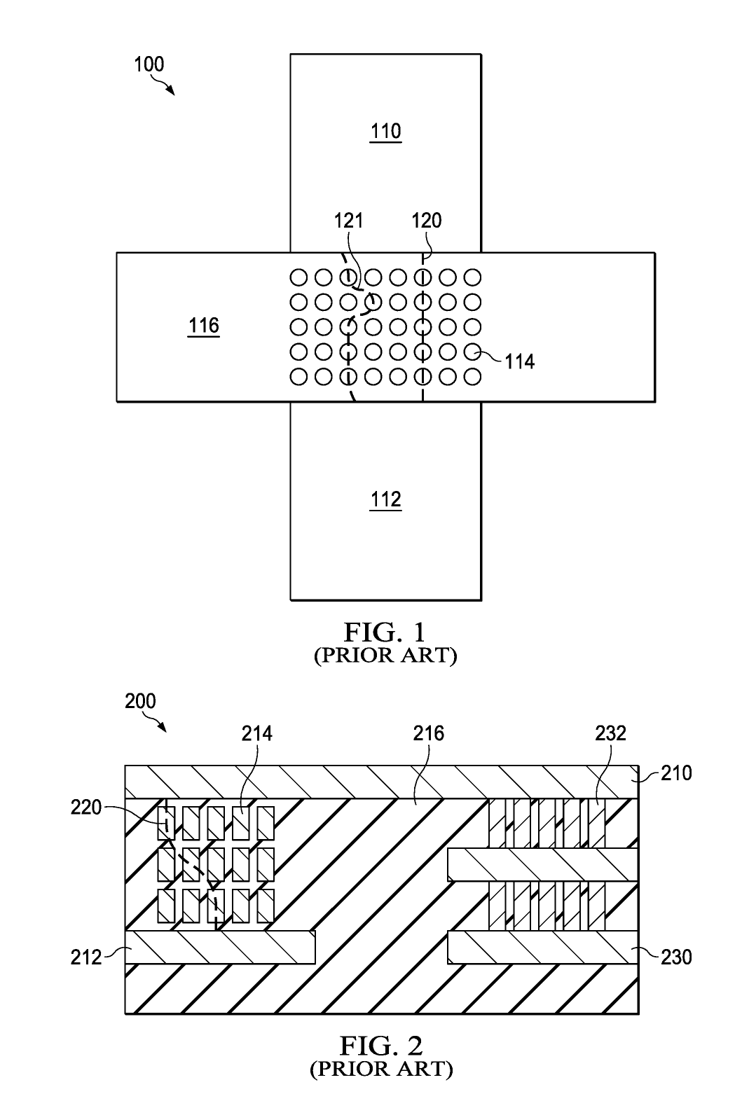

FIG. 1 is a top view of a pillar style spark gap ESD device. In the top view of spark gap device 100, a top signal bond pad 110 is separated from a bottom ground bond pad 112 by a field of isolated conductive pillars 114 that are formed in a dielectric material 116. When the voltage between the bond pads exceeds the threshold voltage for the spark gap device, an arc will form a horizontal path through the conductive pillars as shown by arc 120 for example. With the multitude of pillars 114 buried in the dielectric material 16, heat is well dissipated and that reduces the erosion of the electrode pillars. In the event of erosion on a pillar, on a subsequent trigger, the arc can take a path around an eroded pillar such as arc/spark path 121.

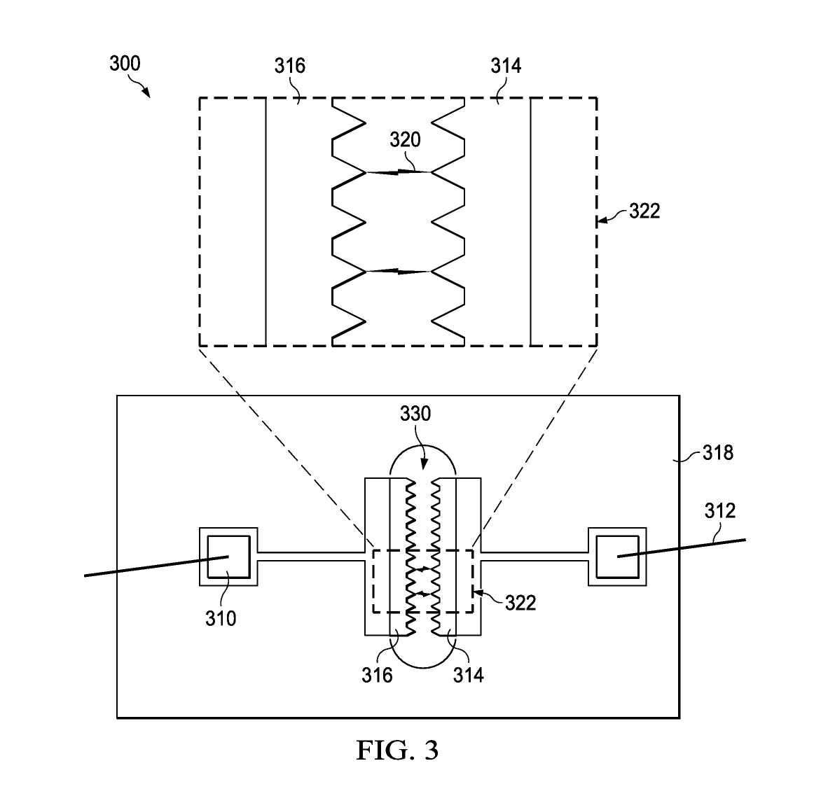

FIG. 2 is a cross sectional view of a conventional spark gap ESD device. In FIG. 2, spark gap device 200 includes a top bond pad 210 that is separated from a bottom ground contact 212 by a field of isolated conductive plugs 214. The conductive plugs 214 are formed in a dielectric material 216. The top bond pad 210 is further connected to multiple metal layers 230 with tungsten pillars 232. When the potential between the bond pad 210 and the ground contact 212 exceed the voltage threshold, an arc will form a vertical path through the plugs 214 as shown in arc/spark path 220 for example.

In examples 100 and 200, the multiple isolated pillars make the break down voltage somewhat independent of erosion on a single pillar. The pillars are made of conductive material such as Al, Cu, W, Au, Ti, TiN, TiW, doped silicon or conductive polymers. The dielectric materials include silicon dioxide, silicon nitride, spin-on glass, non-conductive polymers, vacuum or inert gasses.

New process technologies that enable a range of functional circuit blocks to be isolated from each other on the same silicon die have created a need for effective ESD protection for these devices. An external ESD protection device will not effectively protect the internal circuits in these applications. In one such technology, sections of the silicon are completely isolated by front-side or back-side trenching. To ensure mechanical stability, the trenches are then filled with a dielectric that has a breakdown in the range of hundreds of volts, much less than a typical ESD strike voltage. To prevent breakdown of the isolation dielectric, an ESD clamping device is required that is compatible with the semiconductor processing. Conventional junction based ESD devices would consume large amounts of silicon area. Traditional spark gap ESD devices have reliability issues due to the high thermal resistance between the comb points and the bulk silicon resulting in the erosion or vaporization of the metal points. Also, when conventional spark gap ESD devices are covered during the molding process, reliability issues result from the carbonization of the surrounding mold compound when an arc forms. The carbon tracks formed during the arc often result in undesirable leakage paths.

A new process technology involving using a sacrificial encapsulation material that is removed via sublimation is taught in the '151 Application. In one example described in the '151 Application, a process deposits a sublimatable sacrificial encapsulant material (SSEM) that is later removed by a phase change sublimation process. In the example, the removal of the SSEM allows a die to “float” free of the lead frame, only secured by the bond wires, after the molding process has been completed. In an example embodiment for the present application, the same sacrificial sublimation technology is used in a different manner to create a cavity within the semiconductor package, wherein a spark gap device is contained in the cavity. In both uses of the sublimation technology, a vent is created to allow the sacrificial material to exit the cavity in the gaseous phase.

An example embodiment uses the sublimation technology from the '151 Application to create a void around the electrodes of an integrated spark gap device. In an example application the spark gap device is arranged for ESD protection. The presence of the void results in a predictable and reliable breakdown voltage, and the cavity provides a space with no adjacent material that could otherwise be carbonized by the high temperature plasma arc, preventing leakage. An alternative embodiment described herein below uses a film assisted molding (FAM) technique to form the void for the spark gap.

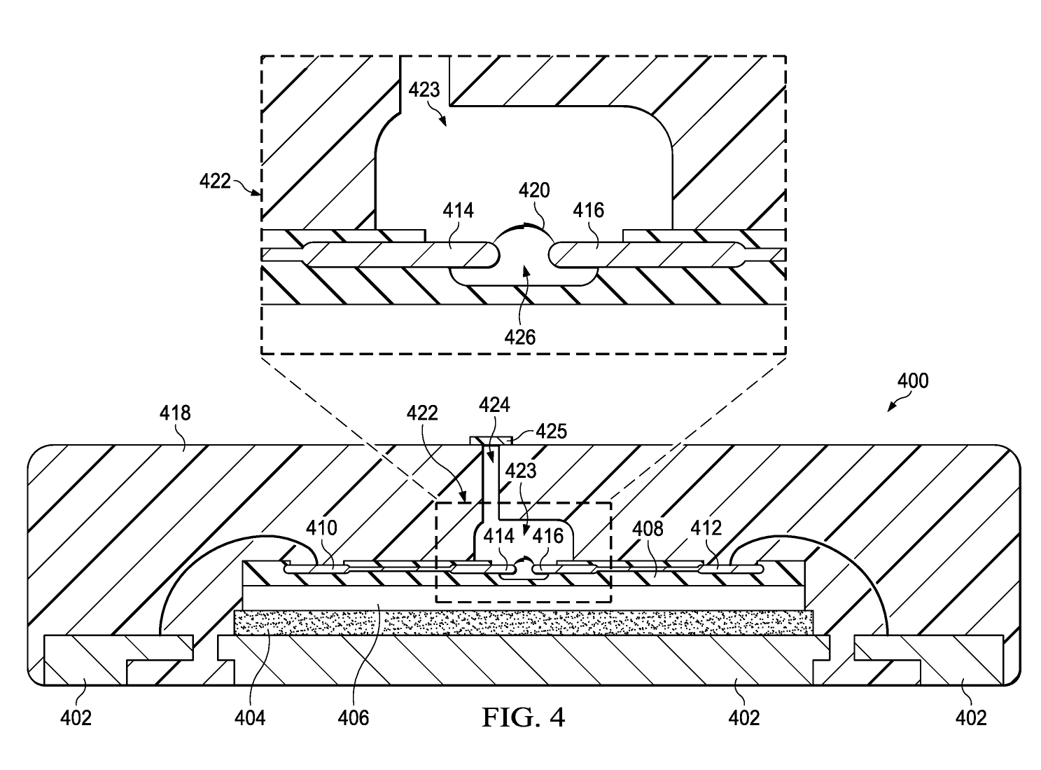

FIG. 3 is a top view of an example embodiment providing a spark gap ESD protection device. In FIG. 3, the spark gap ESD protection device 300 includes a first bond pad 310 coupled to a second bond pad 312 by a pair of combed electrodes 314, 316 of an ESD device situated on a substrate 318 material. The substrate can be silicon, GaAs, SiGe or other semiconductor material, or in alternative arrangements, the substrate can be a ceramic or other insulator material carrying conductors. The fingers of the comb electrodes 314 and 316 are suspended above a cavity 330. The cavity 330 is formed using the sublimation process taught in the '151 Application. In an alternative approach, the cavity can be formed using FAM and shapes in a mold tool together to form it.

In operation, when the voltage potential between the two electrodes 314, 316 exceeds a threshold voltage, such as during an ESD event, an arc 320 forms between the electrodes 316 and 314, as seen in the enlarged view labeled 322. The arc 320 creates a short or a very low resistance path that conducts and shunts the high voltage energy away from internal devices, resulting in ESD protection. Once the conditions for the arc no longer exist, the arc self-extinguishes. The area 330 above and below the electrode combs 314, 316 is absent of any material that may carbonize from the high temperature arc.

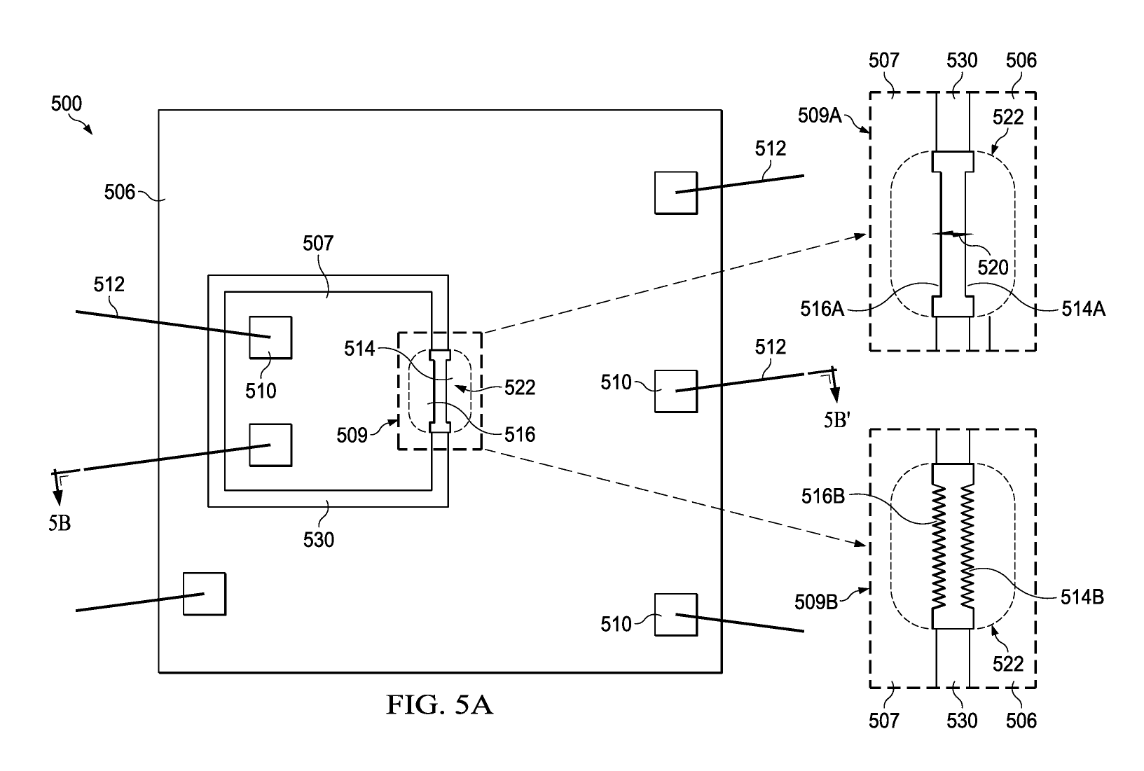

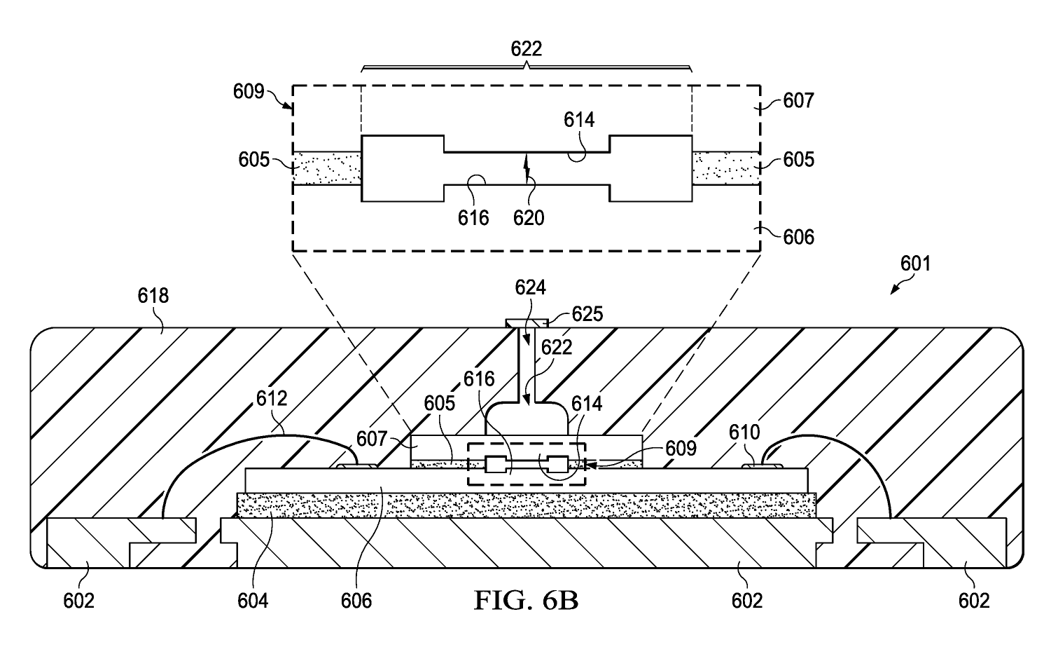

FIG. 4 is a cross sectional view of an example embodiment such as that shown in FIG. 3. In FIG. 4, a spark gap ESD protection device 400 within an integrated circuit package is shown. The spark gap ESD protection device 400 includes a substrate 406 attached to a lead frame 402 with a die attach 404. The substrate 406 is silicon in this example, but the substrate can also be other semiconductor materials such as GaAs, SiGe and other insulating materials such as a ceramic. For example, thick film and hybrid circuits can be built on a ceramic substrate, and these circuits also require ESD protection. The die attach is electrically non-conductive in this example but can be conductive in other example embodiments. The die attach can be a thermal conductor to relieve heat stress on the integrated circuit. Over the silicon substrate 406 is a metal/passivation layer 408. A bond pad 410 is coupled to the bond pad 412 through a pair of electrodes 414 and 416. Above and below the electrodes 414,416 is a void 423 that has a vent 424 and vent cover 425. Mold compound 418 covers the entire assembly forming a semiconductor package. Looking to the enlargement view labeled 422, the void 426 below and the void 423 above the electrodes 414 and 416 totally surrounds the electrodes. An arc 420 is shown bridging the electrodes. In the fabrication of spark gap ESD protection device 400, the electrodes 414 and 416 are formed in a top metal and passivation is applied. After the passivation layer, a patterned etch removes the passivation on top of the electrodes and undercuts a region 426 under the electrodes. The patterned, undercutting etch can be performed using the Advantech etch process. The etch process leaves the portion of the electrodes where the arc will form suspended away from the underlying material. Other etch processes can be used to form the cavity. At this stage of the fabrication, a SSEM is selectively formed and cured over the top of the electrodes in the area 423. Next the assembly process continues through the wire bonding and molding process. The vent 424 is a passage between the SSEM and the surface of the package. The vent 424 can be formed using film assisted molding (FAM) or by a feature in the hard mold similar to a sprue. In the FAM approach, a compliant film conforms to a surface of the mold tool (sometimes assisted with a vacuum to position the film on the mold tool surface) and acts as a gasket to avoid mold flash material from forming on any interference feature, so that the finished packages will release from the mold easily. Vents can also be formed by mechanical drilling or by laser drilling. After the vent 424 has been formed, the sublimation process follows where the SSEM is sublimated through a phase change process resulting in the SSEM exiting as a gas through the vent 424. The cavity 423 formed by the sublimation process is next exposed to ozone to remove any adsorbed organic that might remain on the cavity walls that could lead to carbon whiskers. The void fills with the local atmosphere and is then sealed with a cover 425. The package assembly completes the packaging flow with marking, singulation, ball or stud terminal formation, and/or lead forming when required. The cavity can also be formed using film assisted molding (FAM). This alternative is described hereinbelow with respect to FIG. 7.

In operation, when the voltage potential between the two electrodes 414, 416 exceeds the threshold voltage, such as during an ESD event, an arc 420 forms between the electrodes 414 and 416, as seen in the enlarged view labeled 422. The arc 420 creates a short or very low resistance current path that conducts current away from internal devices and limits the high voltage energy providing ESD protection. Once the conditions for the arc no longer exist, the arc self-extinguishes. The cavity 423 provides for a controlled air dielectric in the spark gap region and prevents contact of the arc 420 with the package mold compound. The spacing between the electrodes and the air dielectric create a predictable voltage threshold for the arc to occur, providing an ESD protection that will trigger when the potential between the electrodes reaches the threshold. The arc provides a short circuit or low resistance path, shunting current away from other circuit components and protecting them from damage during an ESD event.

As a result of the use of the embodiments forming cavities 423 and 426, spacing between the arc and the mold compound or other materials prevents the formation of conductive carbon tracks. Conductive carbon tracks lead to undesirable device leakage. In the example embodiment 400, more than one spark gap can be formed to protect one or more circuits.

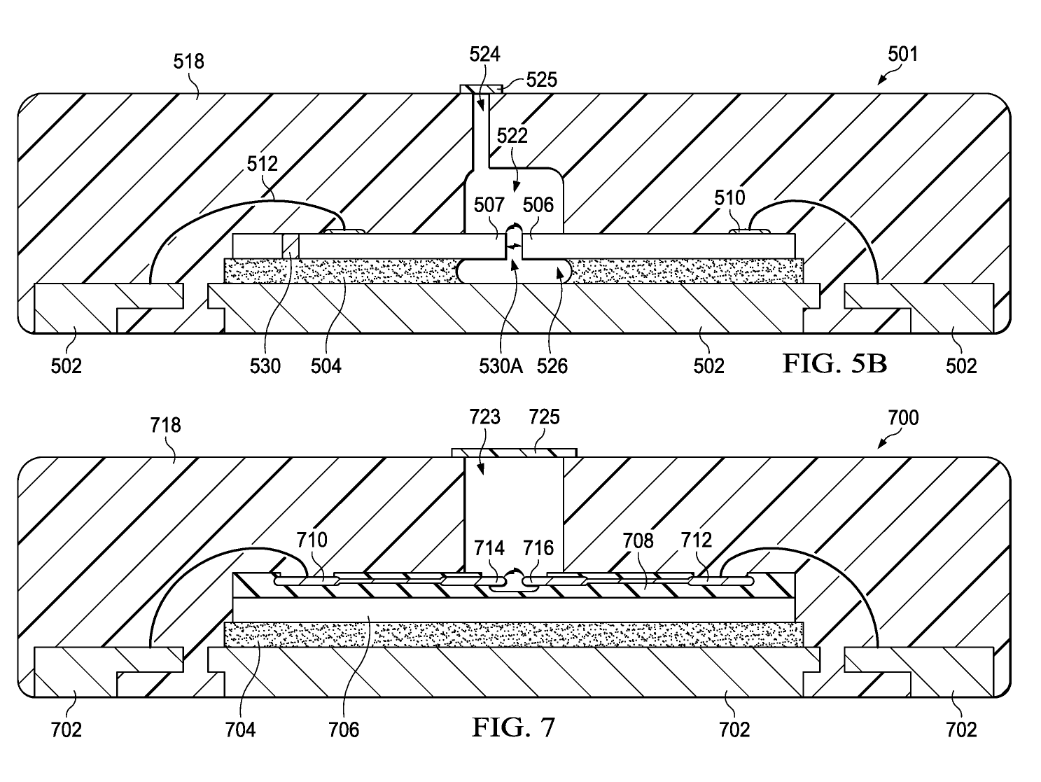

FIGS. 5A and 5B are a top view and cross section view, respectively, of another example embodiment for a spark gap ESD protection device for isolated sub-die in a package. In top view 500 of FIG. 5A, a sub-die 507 and a main die 506 have multiple bond pads 510 with bond wires 512 attached to a lead frame (not shown). A trench 530, formed by known compatible trenching processes, physically and electrically separates the sub-die 507 from main die 506 and later the trench is filled with a compatible dielectric to restore mechanical integrity. In the area 522 is a cavity where the trench is not filled with dielectric, but is absent of materials. In the trenching process a pair of electrodes 516 and 514 are formed in the substrate between the sub-die 507 and main die 506. Many electrode shapes can be formed during the trenching process. View 509A is an expanded view of area 509 and it shows an example embodiment using parallel edge electrode shape of electrodes 516A and 514A. The trench 530 is shown filled with dielectric except in cavity area 522 between the sub-die 507 and main die 506. An arc 520 is shown bridging between the electrodes 516A and 514A in the cavity area 522. View 509B is another expanded view of area 509 and it shows another example embodiment using “comb” shaped edge electrodes 516B and 514B. The trench 530 is shown filled with dielectric except in the cavity area 522 between the sub-die 507 and main die 506.

FIG. 5B is a cross section 501 taken along line 5B-5B′ in FIG. 5A. In cross section 501, the main die 507 and sub-die 506 are attached to the lead frame 502 with die attach 504. Bond wires 512 connect the lead frame 502 to bond pads 510 on the main die 507 and sub-die 506. A filled trench 530 electrically separates the main die 506 and the sub-die 507. A portion of the trench 530 is not filled in the area 530A between the electrodes where cavities 522 and 526 are located. The cavities 522 and 526 encompass an area above and below the die including the area containing the electrodes (not shown in cross section). A mold compound 518 covers the assembly leaving a vent 524 connecting the cavity 522 to the surface of the mold compound. The vent cover 525 seals the vent 524.

In the fabrication of the spark gap ESD protection device 500, after the semiconductor die processing steps have formed the circuit arrangement, a trench 530 is formed around the sub-die 507 to electrically isolate sub-die 507 from the main die 506, and to form the electrode shapes 516 and 514. The trench is subsequently filled with a non-conductive material, such as a compatible dielectric material, to restore mechanical integrity and retain electrical isolation. After the trench 530 is filled, a patterned etch removes the trench material in the spark gap area 522 and the non-conductive die attach material under the substrate, labeled area 526 in FIG. 5B. A SSEM is then selectively applied and cured in area 522 in and around the electrodes 514 and 516. Next the assembly processes continue through wire bonding and molding processes where a vent 524 is formed in the mold compound, leaving a passage from the SSEM to the package surface. The sublimation process follows where the SSEM is sublimated through a phase change process resulting in the SSEM exiting as a gas through the vent 524. The cavities 522 and 526 are then exposed to ozone to remove any adsorbed organic on the cavity walls that could lead to carbon whiskers. At this point, the electrodes 514 and 516 in spark gap areas 522 and 526 have a void below, in-between and above them. The void fills with the local atmosphere and is then sealed with a cover 525. The package assembly completes the packaging flow with marking, singulation, ball or stud terminal formation, and/or lead forming when required.

In operation, referring to expanded view 509A, when the voltage potential between the two electrodes 514A and 516A exceeds the threshold voltage, such as during an ESD event, an arc shown as 520 forms between the electrodes 514A and 516A. The arc 520 creates a short or a very low resistance that conducts current and limits the high voltage energy providing ESD protection. Once the conditions for the arc no longer exist, the arc self-extinguishes. The cavities 522 and 526 provide for a controlled air dielectric in the spark gap region and prevents contact of the arc 520 with the package mold compound and the attach material. As a result of the use of the embodiments forming cavities 522 and 526, spacing between the arc and mold compound or other materials prevents the formation of conductive carbon tracks. Conductive carbon tracks lead to undesirable device leakage. The electrodes 514 and 516 are formed in the substrate so that heat generated by the arc 520 is quickly dissipated, resulting in little or no erosion of the electrodes. In the example embodiment 500, more than one spark gap can be designed between the sub-die 507 and main die 506 to protect one or more circuits. Also, multiple sub-dies 507 can be formed within the main die 506 and in alternative arrangements, each sub-die is formed with spark gap devices.

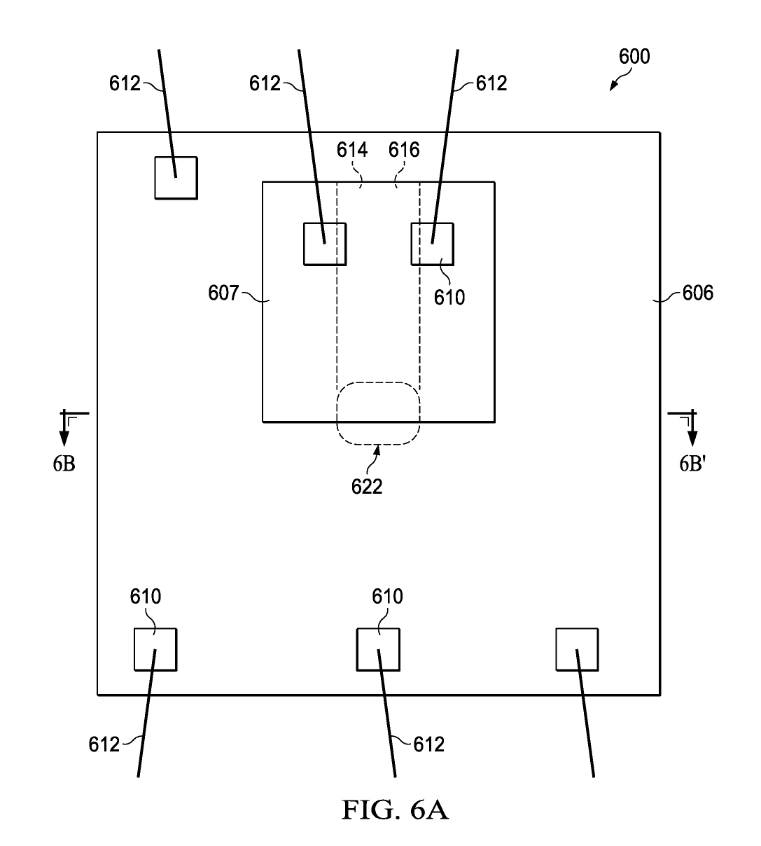

FIGS. 6A and 6B are a top view and a cross section view, respectively, of another example embodiment for a spark gap ESD protection device for a stacked die package. In top view 600 in FIG. 6A, a stacked die 607 is attached to a main die 606. The sub-die 607 and main die 606 have bond pads 610 and bond wires 612. A spark gap electrode 616 on the top side of the main die 606 is aligned to a second spark gap electrode 614 on the bottom side of top die 607 and the electrodes and the portion between the electrodes are surrounded by a cavity 622.

Cross sectional view 601 in FIG. 6B is taken from FIG. 6A along line 6B-6B′. In cross sectional view 601, lead frame 602 has bond wires 612 attached to bond pads 610. The bond pads 610 are located on main die 606 and top die 607. The main die is attached to the lead frame 602 by a die attach 604. The top die 607 is attached to the main die 606 by a die attach 605. A spark gap electrode 616 on the main die 606 is aligned to a second spark gap electrode 614 on the top die 607. A cavity 622 surrounds the electrodes and has a vent 624 and vent cover 625. The entire device is encapsulated with a mold compound 618. In the stacked die package 600, the electrodes 616, 614 can be defined as portions of the semiconductor substrates the main die 606 and the stacked die 607 are formed from. The electrodes can be formed by a silicon etch to pattern a portion of the semiconductor substrate. Metal deposited by sputter or evaporation, then etched can be used to form conductive electrodes on the main die 606 and sub-die 607.

An expanded view 609 of the electrode area shows an arc 620 between the spark gap electrodes 614 and 616 of the top die 607 and main die 606 respectively. Die attach 605 is shown on both sides of the cavity 622.

In the fabrication of the spark gap ESD protection device 600, electrode 616 is formed in the top of the main die 606 by etching a moat around the electrode 616 by known process such as a wet etch. Electrode 614 is formed on the bottom of the top die 607 by etching a moat around the electrode 614 by a wet etch. In the assembly process, the main die 606 is attached to the lead frame 602 with a die attach compound 604 such as epoxy. In the next step, a film die attach 605 is patterned on the first die with a controlled height attach process such as a film attach process. Die attach compound is not applied in the cavity 622 where spark gap electrodes 614 and 616 reside. Next the top die 607 is attached to the main die 606. In this step, the portion of the top die where electrode 614 is located is positioned so that the electrode 614 is over the electrode 616 from the main die 606. After stacked die placement a SSEM is deposited and cured in the cavity region 622 and extending vertically to form a shape above die 607. The assembly then proceeds to wire bonding and molding processes. During the molding process, a vent 624 is formed in the mold compound forming a passage from the SSEM to the package surface. The sublimation process follows where the SSEM is sublimated through a phase change process resulting in the SSEM exiting as a gas through the vent 624. The cavity 522 is then exposed to ozone to remove any adsorbed organic on the cavity walls that could lead to carbon whiskers. At this point, the electrodes 614 and 616 in spark gap area 622 have a void below, in-between and above them. The void fills with the local atmosphere and is then sealed with a cover 625. The package assembly completes the packaging flow with marking, singulation, ball or stud terminal formation, and/or lead forming when required.

Reference is made to expanded view 609 in FIG. 6B. When the voltage potential between the two electrodes 614 and 616 exceeds the threshold voltage, such as during an ESD event, an arc 620 forms between the electrodes 614 and 616. The arc 620 creates a short or very low resistance that conducts and limits the high voltage energy providing ESD protection. Once the conditions for the arc no longer exist, the arc self-extinguishes. The cavity 622 provides for a controlled air dielectric in the spark gap region and prevents contact of the arc 620 with the package mold compound and die attach material. As a result of the use of the embodiments forming cavity 622, spacing between the arc and die attach or other materials prevents the formation of conductive carbon tracks. Conductive carbon tracks lead to undesirable device leakage. In the example embodiment 600, more than one spark gap can exist between the stacked die 607 and main die 606 to protect one or more circuits. Also, multiple stacked die 607 can be attached each with their own spark gap devices.

FIG. 7 is a cross sectional view of another alternative example embodiment 700 for a spark gap ESD protection device within an integrated circuit package. In FIG. 7, similar reference labels are used for similar elements in FIG. 4, for clarity. For example, the substrate 706 in FIG. 7 corresponds to the substrate 406 in FIG. 4. In FIG. 7, the spark gap ESD protection device 700 includes a substrate 706 attached to a lead frame 702 with a die attach 704. The substrate 706 can be silicon or the substrate can also be other semiconductor materials, such as GaAs and SiGe. The substrate can also be formed from other insulating materials such as ceramic. For example, thick film and hybrid circuits can be built on a ceramic substrate. The die attach 704 is electrically non-conductive in this example and can be conductive in other example embodiments. The die attach can be a thermal conductor to relieve heat stress on the integrated circuit. Over the substrate 706 is a metal/passivation layer 708. A bond pad 710 is coupled to the bond pad 712 through a pair of electrodes 714 and 716. Above and below the electrodes 714, 716 is a cavity 723 that extends vertically upwards to the exterior of a mold compound 718. The cavity 723 is covered by a cover or film 725. Mold compound 718 covers the entire assembly forming a semiconductor package.

In the alternative arrangement of FIG. 7, the cavity 723 can be formed using film assisted molding (FAM). As described hereinabove, when using FAM a compliant film is applied to the top and bottom portions of a mold tool and is used so that the finished molded packages will release from the mold easily. The FAM material can be used in conjunction with a pattern in the top portion of a mold tool to form the cavity by preventing the mold compound from entering the cavity area. The cavity 723 fills with the local atmosphere and is then sealed with a cover 725. The package assembly completes the packaging flow with marking, singulation, ball or stud terminal formation, and/or lead forming when required.

In operation, when the voltage potential between the two electrodes 714, 716 exceeds the threshold voltage, such as during an ESD event, an arc (not shown in FIG. 7) will form between the electrodes 714 and 716, as described hereinabove with respect to FIG. 4. The arc creates a short or very low resistance current path that conducts current. In an ESD event, the arc and the electrodes direct the current away from internal devices and limits the high voltage energy, providing ESD protection. Once the conditions for the arc no longer exist, the arc self-extinguishes. The cavity 723 provides for a controlled air dielectric in the spark gap region and prevents contact of the arc with the package mold compound.

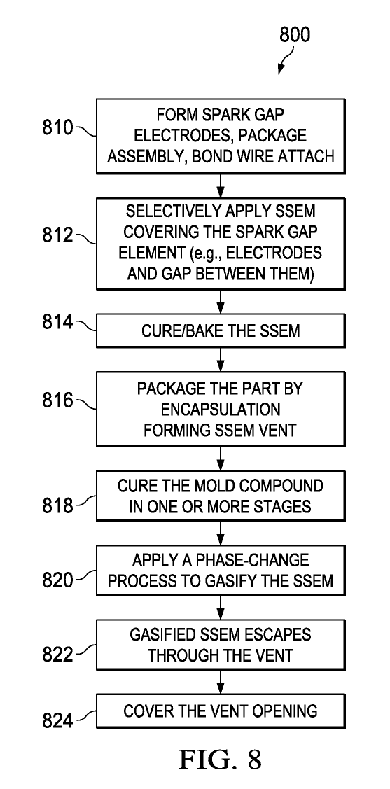

FIG. 8 shows in a flow diagram the steps for a method embodiment using SSEM. In FIG. 8, the method 8000 begins at step 810, one or more integrated circuit devices are formed with electrodes, the electrodes spaced from one another to form a spark gap between them, and the remainder of the package assembly steps including die attach and bonding wire attach are completed. At step 812, the SSEM material is applied to cover the spark gap element including at least the ends of the adjacent electrodes and the gap between them. At step 814, the SSEM is cured, for example, by baking or UV cure, depending on the material. At step 816, an encapsulation step is performed to complete the package body and form the SSEM vent. In one example, thermoplastic mold compound is heated and transfer molding is used to force the liquid mold compound into a mold including the integrated circuit. In alternative arrangements, liquid injection molding can be used. FAM can be used to aid in forming the vent, and to aid in releasing the completed packages from the mold tool. At step 818, the mold compound is cured in one or more stages. At step 820, a phase change process is applied to the SSEM to gasify the SSEM material. At step 822, the gasified SSEM is allowed to escape the package, for example, by use of a vent in the encapsulation material. At step 824, the vent is covered. Additional method steps used to complete an integrated circuit package, such as singulation, marking, ball or stud bumping, lead trim and form, and testing can be performed following step 824.

In an alternative method, the cavity is formed using FAM to form a void in a mold tool surrounding at least the end portions of the electrodes and the gap as shown in FIG. 7 hereinabove. The encapsulation process continues with the FAM and the mold tool preventing the void from filling with mold compound to define the cavity. In this alternative method, the steps described in FIG. 8 for placing the SSEM material, curing the SSEM material, forming a vent, and removing the SSEM material using sublimation, are omitted. The cavity formed in this alternative method embodiment also surrounds the ends of the electrodes and the gap, and an arc formed in the cavity is spaced from the surrounding mold compound, preventing carbonization.

The spacing between the electrodes and the air dielectric create a predictable voltage threshold for the arc to occur, providing an ESD protection that will trigger when the potential between the electrodes reaches the threshold. The arc provides a short circuit or low resistance path, shunting current away from other circuit components and protecting them from damage during an ESD event.

Modifications are possible in the described embodiments, and other embodiments are possible within the scope of the claims

1. An apparatus, comprising:
an integrated circuit die having multiple terminals;
a leadframe having a die pad portion, the integrated circuit die positioned on and attached to the die pad portion;
the leadframe having leads for external connections, at least some of the leads having an inner portion electrically coupled to at least one terminal selected from the multiple terminals of the integrated circuit die;
a first electrode having a first end portion, the first electrode formed in a passivation layer overlying the integrated circuit die, the first end portion exposed from the passivation layer by a void in the passivation layer;
a second electrode having a second end portion positioned proximal to and spaced from the first end portion of the first electrode, the second electrode formed in the passivation layer, the second end portion exposed from the passivation layer by the void in the passivation layer, the first end portion and the second end portion spaced by a spark gap;
encapsulation material surrounding the integrated circuit die, the passivation layer, the void in the passivation layer, the first and second electrodes and the spark gap to form a packaged integrated circuit;
a cavity in the encapsulation material overlying the void in the passivation layer; and
the cavity and the void surrounding the first end portion of the first electrode, the second end portion of the second electrode and the spark gap; the first end portion of the first electrode, the second end portion of the second electrode and the spark gap spaced from the encapsulation material and spaced from the passivation layer.

2. The apparatus of claim 1, in which the cavity and the void in the encapsulation material surrounding the spark gap are filled with air.

3. The apparatus of claim 2, and further including a vent extending from the cavity to an external surface of the encapsulation material.

4. The apparatus of claim 3, and further including a cover material covering the vent at an exterior surface of the encapsulation material.

5. The apparatus of claim 1, in which the first electrode overlies the integrated circuit die and is coupled to a first conductor further coupled to at least one of the multiple terminals of the integrated circuit die, and the second electrode overlies the integrated circuit die and is coupled to a second conductor that is further coupled to at least one other of the multiple terminals of the integrated circuit die; the first electrode, the first conductor, the second electrode and the second conductor coupled to form a path for an ESD current when an arc is present in the spark gap.

6. The apparatus of claim 1, in which the first electrode is formed from a first portion of the integrated circuit die and the second electrode is formed from a second portion of the integrated circuit die that forms a sub-die that is physically and electrically isolated from the first portion.

7. The apparatus of claim 1 in which the first end portion of the first electrode and the second end portion of the second electrode are comb shaped.

8. The apparatus of claim 1 in which the first end portion of the first electrode and the second end portion of the second electrode are symmetric.

9. The apparatus of claim 1, in which the first electrode is formed from a first portion of the integrated circuit die and the second electrode is formed from a portion of a second integrated circuit stacked die that is overlying at least a portion of the integrated circuit die.

10. The apparatus of claim 1, in which the cavity is formed using one selected from a sublimatable sacrificial encapsulant material (SSEM) surrounding the spark gap, and a film assisted molding material forming the cavity in a mold tool.

11. The apparatus of claim 1, in which the spark gap, the first electrode, and the second electrode are to form a short circuit in an ESD strike condition due to an arc forming between the first end portion and the second end portion in the spark gap.

12. A method, comprising:
attaching an integrated circuit die to a die pad portion of a leadframe, the integrated circuit die having a plurality of terminals;
electrically coupling terminals of the leadframe to at least one of the plurality of terminals of the integrated circuit die;
forming a first electrode and a second electrode in a passivation layer overlying a surface of the integrated circuit die;
positioning a first end portion of the first electrode proximate a gap, the first end of the first electrode and the gap exposed from the passivation layer by a void formed in the passivation layer;
positioning a second end portion of the second electrode proximate the gap and spaced from the first end portion of the first electrode, the second end portion of the second electrode in the void in the passivation layer; the first electrode, the second electrode and the gap forming a spark gap proximate to the integrated circuit die;
forming a cavity aligned with and overlying the void in the passivation layer;
the cavity and the void in the passivation layer surrounding the first end portion of the first electrode, the second end portion of the second electrode and the spark gap; and
forming an integrated circuit package of encapsulation material; the first end portion of the first electrode, the second end portion of the second electrode and the spark gap positioned in the void and spaced from the encapsulation material by the cavity and spaced from the passivation layer by the void.

13. The method of claim 12, in which forming the cavity further includes:
applying sacrificial sublimatable encapsulant material (SSEM) to surround the first end portion of the first electrode, the second end portion of the second electrode, and the gap;
curing the SSEM;
encapsulating the integrated circuit die, the leadframe, and the SSEM to form the integrated circuit package of encapsulation material, the SSEM forming a cavity in the encapsulation material, the first end portion of the first electrode, the second end portion of the second electrode and the gap positioned in the cavity and spaced from the encapsulation material;
forming a vent in the encapsulation material extending from an external surface of the encapsulation material to the cavity; and
applying a phase change process to gasify the SSEM, and allowing the SSEM to escape through the vent.

14. The method of claim 12, in which forming the cavity includes:
defining the cavity as a void surrounding the first end portion of the first electrode, the second end portion of the second electrode and the gap using a mold tool and film assisted molding material;
encapsulating the integrated circuit die, the leadframe, and the void to form the integrated circuit package of encapsulation material, the mold tool and the film assisted molding material preventing the encapsulation material from entering the void and forming the cavity in the encapsulation material, the first end portion of the first electrode, the second end portion of the second electrode and the gap positioned in the cavity and spaced from the encapsulation material; and
removing the film assisted molding material from the integrated circuit package to complete the cavity.

15. The method of claim 12, and further including forming a sub-die from a portion of the integrated circuit die and electrically isolating the sub-die from the remainder of the integrated circuit die, in which the first electrode is a portion of the integrated circuit die, and the second electrode is a portion of the sub-die.

16. The method of claim 12 and further including stacking a stacked die over the integrated circuit die, the stacked die covering at least a portion of the integrated circuit die, in which the first electrode is a portion of the integrated circuit die, and the second electrode is a portion of the stacked die.

17. The method of claim 12, in which the first electrode is coupled to at least one of the plurality of terminals of the integrated circuit die by a first conductor overlying the integrated circuit die, and the second electrode is coupled to at least another one of the plurality of terminals of the integrated circuit die by a second conductor overlying the integrated circuit die, and the first conductor, first electrode, second electrode and second conductor form a current path including an arc in the spark gap when a voltage over a threshold forms between the first electrode and the second electrode.

18. An integrated circuit with ESD protection, comprising:
an integrated circuit die having terminals;
a leadframe having a die pad portion, the integrated circuit die positioned on and attached to the die pad portion;
the leadframe having leads for external connections, at least some of the leads having an inner portion electrically coupled to at least one of the terminals of the integrated circuit die;
a first conductor overlying a portion of the integrated circuit die and coupled between at least one of the terminals of the integrated circuit die and a first electrode formed in a passivation layer, the first electrode having a first end portion positioned proximate a gap; the first end and the gap in a void in the passivation layer and exposed from the passivation layer by the void;
a second conductor overlying a portion of the integrated circuit die and coupled between at least one of the terminals of the integrated circuit die and a second electrode having a second end portion positioned proximal to the gap and spaced from the first end portion of the first electrode; the second electrode formed in the passivation layer; the second end portion in the void in the passivation layer and exposed from the passivation layer by the void;
the first end portion and the second end portion spaced apart by a spark gap;
encapsulation material surrounding the integrated circuit die, the passivation layer, the void in the passivation layer, the first and second electrodes and the spark gap to form a packaged integrated circuit; and
a cavity in the encapsulation material, the cavity aligned with the void in the passivation layer; the cavity and the void surrounding the first end portion of the first electrode, the second end portion of the second electrode, and the spark gap; the first end portion of the first electrode, the second end portion of the second electrode and the spark gap spaced from the encapsulation material by the cavity and spaced from the passivation layer by the void.

19. The integrated circuit with ESD protection of claim 18, in which the void contains air.

20. The integrated circuit with ESD protection of claim 18, in which the spark gap is a gap of a distance such that when a voltage greater than a predetermined threshold forms between the first electrode and the second electrode, an arc will form a current carrying path between the first electrode and the second electrode in the spark gap.
